(19) United States
(12) Patent Application Publication
(10) Pub. No.: US 2025/0331200 A1
(43) Pub. Date: Oct. 23, 2025

(54) INTEGRATED CIRCUIT DEVICE WITH THIN-FILM RESISTOR USING POSITIVE AND NEGATIVE TEMPERATURE COEFFICIENTS OF RESISTANCE

(71) Applicant: Taiwan Semiconductor Manufacturing Company, Ltd., Hsinchu (TW)

(72) Inventors: Tzu-Yu Lin, Taoyuan City (TW); Bo-Han Chu, Taipei City (TW); Yao-Wen Chang, Taipei (TW)

(21) Appl. No.: 19/254,304

(22) Filed: Jun. 30, 2025

Related U.S. Application Data
(63) Continuation of application No. 18/627,813, filed on Apr. 5, 2024.
(60) Provisional application No. 63/611,905, filed on Dec. 19, 2023.

(51) Int. Cl. H10D 1/47; H01L 23/522

(52) U.S. Cl. CPC H10D 1/474; H01L 23/5228

(57) ABSTRACT

Some embodiments relate to an integrated circuit (IC) device including a thin-film resistor (TFR) overlying a substrate and including a first film and a second film that are stacked in a direction transverse to a top surface of the substrate. The first film includes a first material having a negative temperature coefficient of resistance (TCR) within a temperature range. The negative TCR causes a resistance of the first film to decrease as a temperature of the first film increases. The second film includes a second material having a positive TCR within the temperature range. The positive TCR causes a resistance of the second film to increase as a temperature of the second film increases.

### REFERENCE TO RELATED APPLICATIONS

This Application is a Continuation of U.S. application Ser. No. 18/627,813, filed on Apr. 5, 2024, which claims the benefit of U.S. Provisional Application No. 63/611,905, filed on Dec. 19, 2023. The contents of the above-referenced Patent Applications are hereby incorporated by reference in their entirety.

### BACKGROUND

Thin-film technology has been applied to a number of different types of components within the integrated circuit (IC) environment. Such components include transistors, capacitors, resistors, inductors, and so on. Thin-film resistors, for example, are particularly important in low-resistivity, low-temperature applications, such as haptic drivers, wearable devices, and the like. Consequently, at such low resistivity values, an important characteristic of a thin-film resistor may be providing a stable resistance value over a desired temperature range.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A through 1D illustrate schematic cross-sectional views of some embodiments of thin-film resistor (TFR) structures of an integrated circuit (IC) device employing a material with a positive thermal coefficient of resistance (TCR) and a material with a negative TCR, according to the present disclosure.

FIG. 2 illustrates conceptual graphs of sheet resistance versus temperature related to some embodiments of an IC device employing a TFR structure having a material with a positive TCR and a material with a negative TCR, according to the present disclosure.

FIG. 3 illustrates a cross-sectional view of some embodiments of an IC device employing a TFR structure having a material with a positive TCR and a material with a negative TCR, according to the present disclosure.

FIGS. 4A through 4D illustrate cross-sectional views of some embodiments of IC devices associated with the TFR structures of FIGS. 1A through 1D, respectively, according to the present disclosure.

FIGS. 5A through 5K illustrate cross-sectional views of some embodiments of an IC device employing a TFR structure, as shown in FIGS. 1C and 4C, at various stages of manufacture, according to the present disclosure.

FIG. 6 illustrates a block diagram of some embodiments of a methodology of forming an IC device employing a TFR structure, according to the present disclosure.

FIGS. 7A and 7B illustrate schematic representations of forming a first material and a second material, respectively, of a TFR structure of an IC device, according to the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The “resistivity”, or the ability to resist electrical current, of a material is sometimes characterized as a volume resistivity, or “bulk resistivity,” denoted as p, and stated in units of ohm-meters (Ω-m) or ohm-centimeters (Ω-cm). Using this volume resistivity value, a resistance R (in ohms (Ω)) of a particular sample of the material having a cross-sectional area A (e.g., a rectangular area of width W and thickness t) through which electrical current may flow, and having a length L along which the current may flow, may be determined using the bulk resistivity by way of the relationship R=ρ(L/A)=ρ(L/Wt).

In the case of a thin-film resistor (sometimes referred to herein as a TFR), in which the uniform thickness t of the resistor is significantly less that the width W and the length L of the TFR, a different measure of resistivity, called “sheet resistance” or “surface resistance,” denoted as Rₛ and stated in units of ohms per square (Ω/□), is sometimes used to characterize the TFR. Further, if the thickness t of the TFR is known, the bulk resistivity of the TFR can be calculated from the sheet resistance Rₛ by way of the relationship ρ=Rₛ×t. Additionally, the resistance R of the TFR is R=(ρ/t)(L/W)=Rₛ(L/W), wherein the length L and the width W are the two dimensions of the TFR seen in a plan view.

Presuming that proper operation of a circuit employing a TFR depends upon a stable resistance R of the TFR over a temperature range of interest, and that the resistance R depends upon sheet resistance Rₛ, a stable value of sheet resistance Rₛ over that same temperature range may be desirable. Unfortunately, such stability in sheet resistance Rₛ may be difficult to achieve in the thin-film environment, including at low temperature values (e.g., greater than or equal to −40 degrees Celsius (° C.)). More specifically, a stable resistance over some temperature range depends upon a low “temperature coefficient of resistance” (TCR) over that same range. TCR, which is sometimes denoted as a, specifies a rate of change in resistance or resistivity relative to temperature by way of a value that may change with temperature.

To address these issues, the present disclosure provides some embodiments of an IC device that employs a thin-film resistor (TFR) structure that includes at least two films that include two different materials. In some embodiments, a first material may have a negative TCR within a particular temperature range, and a second material may have a positive TCR within the same temperature range. Accordingly, in some embodiments, electrical current may flow through both the first and second materials in parallel (e.g., in a direction orthogonal to the thickness of the TFR structure) such that a combined TCR numerically between the positive and negative TCRs of the first and second materials (e.g., a combined TCR closer to zero than either TCR for the first or second material) may be produced for the TFR structure over that same temperature range. For example, the overall or combined TCR of the TFR structure that includes the at least two films may maintain a low (e.g., near-zero) TCR value (e.g., less than approximately 50 parts per million per degree Celsius (ppm/° C.)) over the temperature range (e.g., approximately −40° C. to approximately +125° C.). Use of such a TFR structure, embodiments of which are discussed in greater detail below, may thus provide a stable sheet resistance Rₛ and associated resistance R over the desired temperature range, thus facilitating desirable operation of various circuits and devices. Such circuits and devices may include, but are not limited to, haptic drivers and wearable devices, as well as analog-to-digital (ADC) converters in medical equipment, audio applications, and precision controls and instrumentation.

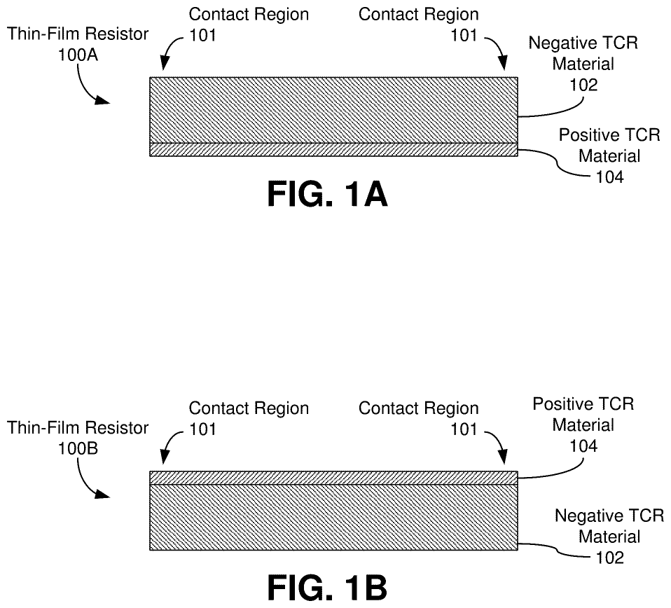

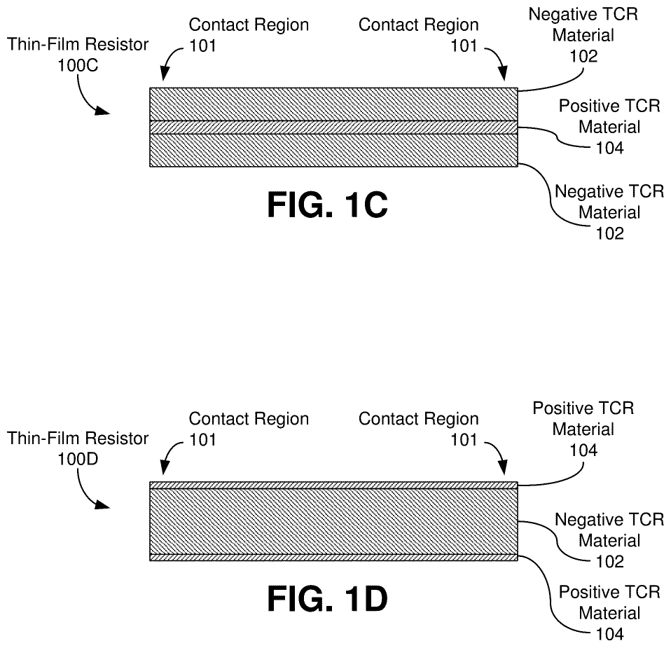

FIGS. 1A through 1D illustrate schematic cross-sectional views of some embodiments of TFR structures 100A through 100D, respectively (more generally, TFR structure 100) of an integrated circuit (IC) device employing one or more films of a negative thermal coefficient of resistance (TCR) material 102 over a particular temperature range and one or more films of a positive TCR material 104, according to the present disclosure. The negative TCR material 102 has a resistance that decreases as a temperature of the one or more films (e.g., the negative TCR material) increases, while the positive TCR material 104 has a resistance that increases as a temperature of the one or more films (e.g., the positive TCR material) increases.

In some embodiments, the negative TCR material 102 and the positive TCR material 104 comprise conductive films. In some embodiments, the negative TCR material 102 may include a nitride base material (e.g., a nitride of a metal, such as tantalum nitride (TaN, or more generally, TaNₓ), titanium nitride (TiN), or the like), and the positive TCR material 104 may include a metal (e.g., tantalum (Ta), titanium (Ti), or the like), such as an associated metal of the nitride base material of the negative TCR material 102.

In each of FIGS. 1A through 1D, contact regions 101 (e.g., for electrodes that may electrically couple the TFR structure 100 to other components of the IC device) are generally marked at or near opposite ends of TFR structure 100. In some embodiments, the contact regions may be at an upper surface or a lower surface of TFR structure 100, within either or both negative TCR material 102 and positive TCR material 104, at an end of either or both negative TCR material 102 and positive TCR material 104, and so on. As a result, in some embodiments, during operation, electrical current may be understood to flow between contact regions 101 (e.g., between the left and right ends of TFR structure 100, as viewed by the reader).

Further, in each of FIGS. 1A through 1D, while the films including negative TCR material 102 and positive TCR material 104 are depicted as laying atop one another, and thus are in contact with each other, other embodiments, such as side-by-side positioning of the films, either in contact with each other or separated from one another, are also possible, but are not explicitly discussed herein to simplify the discussion presented below.

Because of the relationship between the films and/or the coupling between the films, the films including negative TCR material 102 are electrically coupled in parallel with the films including positive TCR material 104. As such, individual resistances of the films combine in parallel and yield a combined resistance that is low compared to the individual resistances.

In addition, in each of FIGS. 1A through 1D, the films of negative TCR material 102 and the films of positive TCR material 104 are shown as having different thicknesses. In some embodiments, the relative thicknesses of negative TCR material 102 and positive TCR material 104 may affect the combined TCR, and thus the overall variation, of sheet resistance Rₛ, of TFR structure 100. More specifically, in some embodiments, a particular ratio of the total thickness of the films of negative TCR material 102 to the total thickness of the films of positive TCR material 104 may yield a minimum variation in sheet resistance Rₛ over a desired temperature range. More specifically, in some embodiments, to balance a relatively high TCR magnitude of positive TCR material 104 against a relatively low TCR magnitude of negative TCR material 102, a correspondingly thicker negative TCR material 102 relative to that of positive TCR material 104 may be employed to minimize the combined TCR. Similarly, to balance a relatively high TCR magnitude of negative TCR material 102 against a relatively low TCR magnitude of positive TCR material 104, a correspondingly thicker positive TCR material 104 relative to that of negative TCR material 102 may be employed to minimize the combined TCR. In some embodiments, a ratio of the total thickness of the films of negative TCR material 102 to the total thickness of the films of positive TCR material 104 may be initially approximated using a theoretical ratio of the TCR (e.g., average TCR) of positive TCR material 104 to the TCR (e.g., average TCR) of negative TCR material 102. In some embodiments, a strict application of this theoretical ratio may not yield a minimized combined TCR (e.g., due to variations in the composition and structure of layers of negative TCR material 102 and positive TCR material that may occur during and/or after fabrication). In some embodiments, the theoretical ratio may be within 20 percent of an actual thickness ratio that results in a minimized combined TCR for TFR structure 100. Thereafter, empirical testing of actual fabricated examples of TFR structure 100 using a number of thickness ratios may be employed to determine a minimized combined TCR.

Further, in some embodiments, the overall sheet resistance Rₛ of TFR structure 100 may be modified by altering the thickness of both negative TCR material 102 and positive TCR material 104 (e.g., while maintaining a desired ratio of the thicknesses). More specifically, increasing the thicknesses may decrease the overall sheet resistance Rₛ of TFR structure 100, while decreasing the thicknesses may increase the overall sheet resistance Rₛ of TFR structure 100.

In some embodiments, presuming a positive TCR material 104 of tantalum (Ta) and a negative TCR material 102 of tantalum nitride (TaN), a ratio of the total thickness of the films of positive TCR material 104 to the total thickness of the films of negative TCR material 102 may range from approximately 0.11 to approximately 0.22. For example, the total thickness of the films of positive TCR material 104 may range from approximately 50 to approximately 150 angstroms (Å), while the total thickness of the films of negative TCR material 102 may range from approximately 1100 Å to approximately 1400 Å. Such a range of ratios may result in a combined TCR for TFR structure 100 of less than approximately 50 ppm/° C. over a temperature range extending at least from approximately −40 to approximately +125° C. More specifically, in some embodiments, the ratio of the total thickness of the films of tantalum (Ta) to the total thickness of tantalum nitride (TaN) may be in a range of between approximately 0.10 and approximately 0.20, approximately 0.16, or other similar values. Using such a ratio, in some embodiments, may yield a combined TCR of less than approximately 5.7 ppm/° C.

Further, in some embodiments, negative TCR material 102 (e.g., a nitride base material, as mentioned above) may provide a range of nitrogen concentration and/or a crystalline structure to facilitate a consistent and acceptable negative TCR and low overall sheet resistance Rₛ. For example, in the case of tantalum nitride (TaN), the percentage of nitrogen (N) therein may be in a range of 29-32 percent (%) and the percentage of tantalum (Ta) may be 67-69%, resulting in an N/Ta ratio of approximately 0.43 to approximately 0.46. Such a concentration may be confirmed, for example, by way of x-ray photoelectron spectroscopy (XPS) analysis. In some embodiments, higher levels of nitrogen in the tantalum nitride may increase the magnitude of the TCR of negative TCR material 102, but may also increase the amount of diffusion of nitrogen from the tantalum nitride to the tantalum of positive TCR material 104, thus altering the characteristics of positive TCR material 104.

Also, in some embodiments, the tantalum nitride (TaN) employed as negative TCR material 102 may desirably have a (110) hexagonal orientation structure, as specified according to Miller index nomenclature, which may be confirmed by way of x-ray diffraction (XRD) analysis. More specifically, this hexagonal structure may result in a relatively low bulk resistivity of approximately 154 micro-ohms-centimeters (μΩ-cm), possibly making such a structure desirable for low resistance applications compared to a body-centered cubic (BCC) (200) structure, which possesses a higher resistivity of 280-480 μΩ-cm.

FIG. 1A is a schematic cross-sectional view of a TFR structure 100A that includes a first film that includes a positive TCR material 104 over a temperature range and a second film that is disposed over (e.g., atop) over the first film and includes a negative TCR material 102 over that same temperature range. In some embodiments, a thickness of the negative TCR material 102 (e.g., in the vertical direction, as depicted in FIG. 1A) is significantly greater than the thickness of the positive TCR material 104. As indicated above, this ratio of thicknesses may determine the amount of variation in sheet resistance Rₛ over a desired temperature range. Accordingly, a selected ratio (e.g., approximated via the theoretical ratio described above, and thereafter possibly refined via experimentation) may yield a desired minimized level of variation in sheet resistance Rₛ over the temperature range. Additionally, in some embodiments, the negative TCR material 102 of the second film may serve as a protective barrier to oxidation and/or nitridation of the underlying first film during the manufacturing process for the IC device in which TFR structure 100A is employed.

FIG. 1B is a schematic cross-sectional view of a TFR structure 100B that includes a first film that includes a negative TCR material 102 and a second film that is disposed over (e.g., atop) the first film and includes a positive TCR material 104. In some embodiments, a thickness of the negative TCR material 102 is significantly greater than the thickness of the positive TCR material 104, and may have the same ratio as that associated with FIG. 1A, which may yield a desired minimized level of variation in sheet resistance Rₛ over a temperature range of interest. Moreover, in some embodiments, negative TCR material 102 serving as the first film may provide adhesion between TFR structure 100B and a dielectric layer atop which TFR structure 100B may reside.

FIG. 1C is a schematic cross-sectional view of a TFR structure 100C that includes a first film that includes a negative TCR material 102, a second film that is disposed over (e.g., atop) the first film and includes a positive TCR material 104, and a third film disposed over (e.g., atop) the second and includes a negative TCR material 102. In some embodiments, a total thickness of the negative TCR material 102 in the first and third films is significantly greater than the thickness of the positive TCR material 104 in the second film. Also, in some embodiments, this ratio may be the same ratio as that associated with FIGS. 1A and 1B, which may yield a minimized level of variation in sheet resistance Rₛ over some temperature range. Moreover, in some embodiments, the negative TCR material 102 of the third film may serve as a protective barrier to oxidation and/or nitridation of the underlying second film during the manufacturing process for the IC device in which TFR structure 100C resides. Further, in some embodiments, negative TCR material 102 of the first film may provide adhesion between TFR structure 100C and a dielectric layer atop which TFR structure 100C may reside.

FIG. 1D is a schematic cross-sectional view of a TFR structure 100D that includes a first film that includes a positive TCR material 104, a second film that is disposed over (e.g., atop) the first film and includes a negative TCR material 102, and a third film disposed over (e.g., atop) the second and includes a positive TCR material 104. In some embodiments, a thickness of the negative TCR material 102 in the second film is significantly greater than the total thickness of the positive TCR material 104 in the first and third films. Also, in some embodiments, this ratio may be the same ratio as that associated with FIGS. 1A, 1B, and 1C, which may yield a minimized level of variation in sheet resistance Rₛ over a temperature range of interest.

While two films are illustrated in FIGS. 1A and 1B, and three films are depicted in FIGS. 1C and 1D, four or more films may be stacked over or atop each other in a TFR structure, where the films alternate between a negative TCR material 102 and a positive TCR material 104. In some embodiments, a ratio of the total thickness of the films of negative TCR material 102 to the total thickness of the films of positive TCR material 104 may determine a combined TCR of the TFR structure, which may minimize a variation in sheet resistance Rₛ over the temperature range of interest.

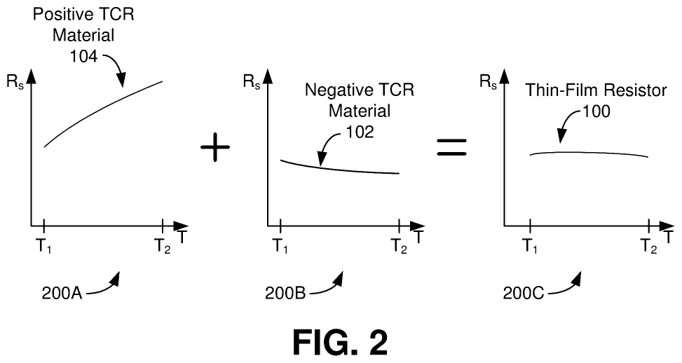

FIG. 2 illustrates conceptual graphs 200A, 200B, and 200C of sheet resistance Rₛ versus temperature T related to some embodiments of an IC device employing a TFR structure 100 having a material 104 with a positive TCR and a material 102 with a negative TCR, according to the present disclosure. More specifically, graphs 200A, 200B, and 200C depict sheet resistance Rₛ versus temperature T for positive TCR material 104, negative TCR material 102, and TFR structure 100, respectively, over a temperature range from T₁ to T₂.

In graph 200A, for example, positive TCR material 104 possesses an increasing sheet resistance Rₛ over the temperature range, while in graph 200B, negative TCR material 102 possesses a decreasing sheet resistance Rₛ over the same temperature range. Consequently, in some embodiments, the slope at each point along graphs 200A and 200B reflects the TCR of the associated material at the particular temperature T at that point. Thus, as depicted in graphs 200A and 200B, the TCR of positive TCR material 104 and the TCR of negative material 102 may change slightly over the temperature range of interest while remaining positive or negative, as graphs 200A and 200B are illustrated as slightly curved instead of strictly linear. In view of the difference in the higher magnitude of the positive TCR values reflected in graph 200A for positive TCR material 104 relative to the negative TCR values reflected in graph 200B for negative TCR material 102, a total thickness of negative TCR material 102 may need to be larger according to some ratio based on the TCR values reflected in graphs 200A and 200B than the total thickness of positive TCR material 104 to produce a combined TCR for TFR structure 100. The positive TCR values of the positive TCR material 104 balance the negative TCR values of the negative TCR material so that an absolute value of the combined TRC of the TFR structure 100 is less than (e.g., is closer to zero than) that of either the positive TCR material 104 or the negative TCR material 102, as shown by the nearly-flat horizontal graph 200C for the sheet resistance Rₛ for TFR structure 100 over the temperature range of T₁ to T₂. In some embodiments, the combined TCR of the TFR structure 100 may be nearly zero. Such a ratio (e.g., a theoretical ratio based on a ratio of the TCR values, possibly altered by way of experimentation, as described above) is depicted in FIGS. 1A through 1D, as discussed in detail above. In other embodiments, in which the TCR values over the temperature range for positive TCR material 104 are less than the TCR values over the same temperature range for negative TCR material 102, the total thickness of the positive TCR material 104 may be greater than the total thickness of the negative TCR material 102 to provide a nearly zero TCR for TFR structure 100 over the temperature range.

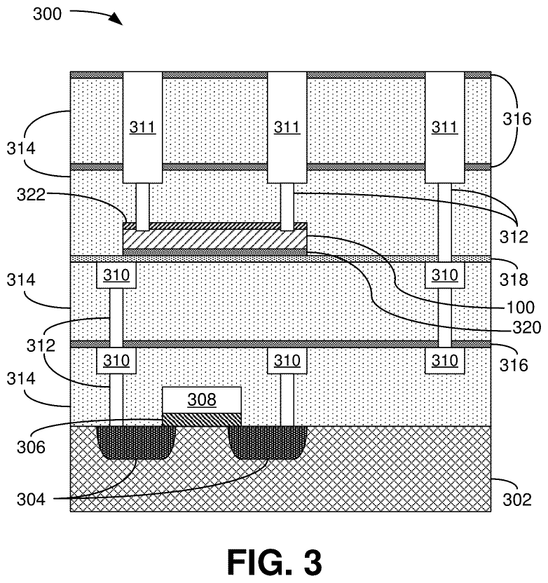

FIG. 3 illustrates a cross-sectional view of some embodiments of an IC device 300 employing a TFR structure 100 having a material 104 with a positive TCR and a material 102 with a negative TCR, according to the present disclosure. As shown, IC device 300 may include a substrate 302 (e.g., a silicon substrate) that may include a plurality of doped or implantation regions 304 (e.g., n-doped regions) that may serve as source-drain regions for transistors. Positioned over substrate 302 may be one or more gate structures 306 and an overlying contact 308 within a dielectric layer 314 (e.g., an inter-level dielectric (ILD) layer). Further located within dielectric layer 314 may be structures 310 (e.g., forming a metal layer) and associated vias 312, some of which may be coupled to doped regions 304. Dielectric layer 314 may include one or more dielectric materials, including, but not limited to, silicon oxide (SiOₓ) (e.g., silicon oxide (SiO₂)), silicon nitride (SiN), silicon carbide (SiC), carbon-doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like.

Disposed over dielectric layer 314 may be an etch stop layer 316. Etch stop layer 316 may include, but is not limited to, silicon nitride (SiN), silicon carbide (SiC), or silicon carbonitride (SiCN). In some embodiments, over etch stop layer 316, one or more additional conductive structures 310 or layers and associate vias 312 within additional dielectric layers 314, as well as one or more additional etch stop layers 316, may be disposed, as illustrated in FIG. 3. Such structures, as well as TFR structure 100, described below, may occur during a back-end-of-line (BEOL) process of IC device 300. In some embodiments, a barrier layer 318 (e.g., silicon carbide (SiC) to provide a high breakdown voltage and/or temperature barrier) may be disposed over substrate 302 and subsequent dielectric layers 314 prior to deposition of materials associated with TFR structure 100.

In some embodiments, over or atop barrier layer 318 may be an oxide layer 320 (e.g., silicon dioxide (SiO₂) or another dielectric material) that serves as a non-conductive base for TFR structure 100 disposed thereon. As discussed above with respect to FIGS. 1A through 1D, TFR structure 100 may include two or more films of negative TCR material 102 (e.g., tantalum nitride (TaN), titanium nitride (TiN), etc.) and positive TCR material 104 (e.g., tantalum (Ta), titanium nitride (Ti), etc.).

Further, in some embodiments, atop TFR structure 100 may be disposed an insulating film 322 (e.g., a nitride base film, such as silicon nitride (SiN), aluminum nitride (AlN), silicon carbide (SiC), or the like) to electrically isolate TFR structure 100 and/or protect TFR structure 100 from environmental factors during fabrication of IC device 300. In some embodiments, insulating film 322 may be at least 200 Å thick.

Electrically connected to TFR structure 100 (e.g., through insulating film 322) may be contacts or vias 312 that may serve as electrodes or terminals for TFR structure 100 to pass current therethrough. In some embodiments, as shown in FIG. 3, the electrodes in the form of vias 312 may extend through insulating film 322 and through an upper surface of TFR structure 100. In some embodiments, the electrodes may extend to the upper surface of TFR structure 100 and/or make contact with a lateral end of TFR structure 100.

Further, in some embodiments, oxide layer 320, TFR structure 100, insulating film 322, and vias 312 may reside within another dielectric layer 314. Moreover, in some embodiments, additional vias, such as through-dielectric vias (TDVs) 311, may extend through an upper surface of IC device 300 to couple to vias 312 serving as electrodes for TFR structure 100. Also, in some embodiments, additional metallization layers of a BEOL process aside from those depicted in FIG. 3 may be included in IC device 300. Further, multiple TFR structures 100 may be include in one or more such metallization layers.

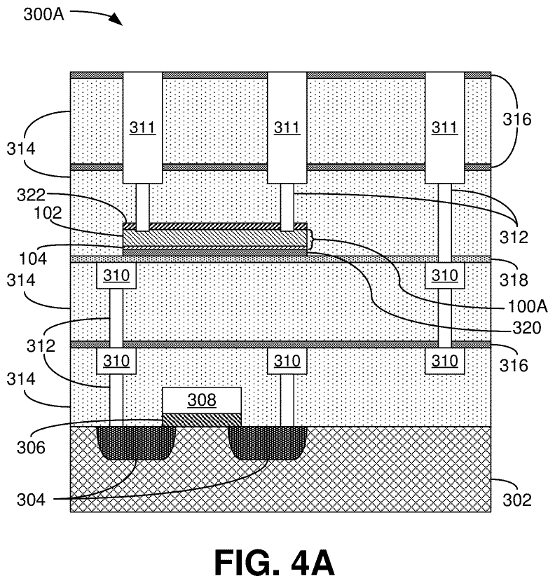

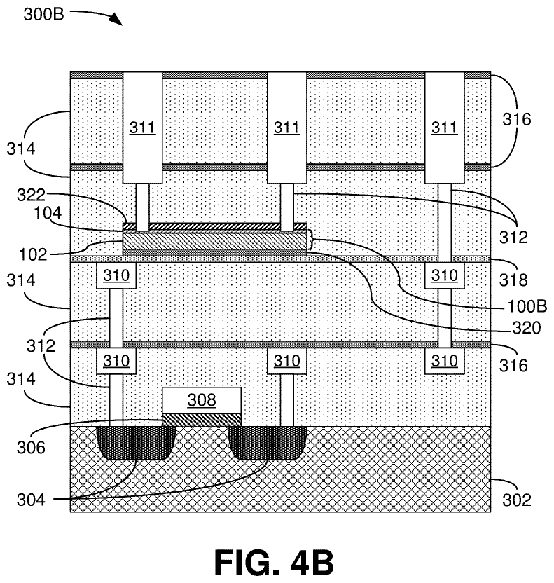

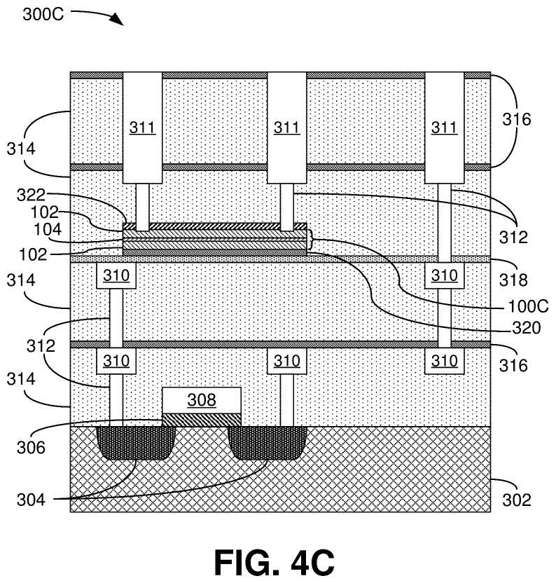

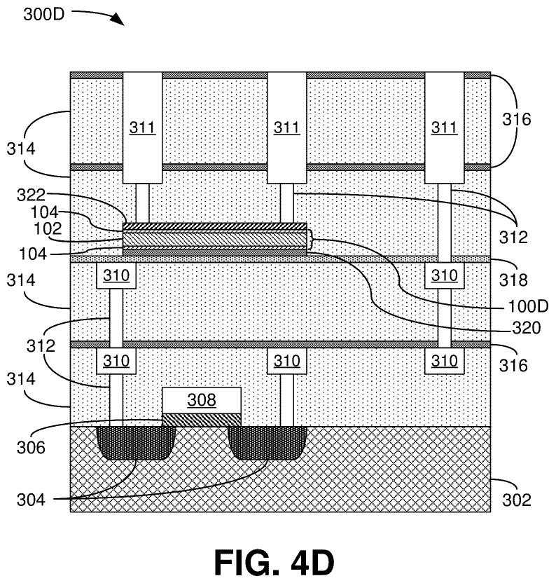

FIGS. 4A through 4D illustrate cross-sectional views of some embodiments of IC devices 300A through 300D, respectively, associated with TFR structures 100A through 100D of FIGS. 1A through 1D, respectively, according to the present disclosure. Aside from differences in TFR structures 100A through 100D, the remaining portions of IC devices 300A through 300D are the same as those described above in conjunction with FIG. 3.

More specifically, FIG. 4A illustrates a cross-sectional view of IC device 300A that includes TFR structure 100A, as described above in relation to FIG. 1A, in which a first film of positive TCR material 104 resides below a second film of negative TCR material 102.

FIG. 4B illustrates a cross-sectional view of IC device 300B that includes TFR structure 100B, as described above in connection with FIG. 1B, in which a first film of negative TCR material 102 is located below a second film of positive TCR material 104.

FIG. 4C illustrates a cross-sectional view of IC device 300C that includes TFR structure 100C, as described above in relation to FIG. 1C, in which a first film of negative TCR material 102 is located under a second film of positive TCR material 104, which is positioned below a third film of negative TCR material 102.

FIG. 4D illustrates a cross-sectional view of IC device 300D that includes TFR structure 100D, as described above in connection with FIG. 1D, in which a first film of positive TCR material 104 resides below a second film of negative TCR material 102, which is located below a third film of positive TCR material 104.

In each of IC devices 300A through 300D, the ratio of the total thickness of the films of negative TCR material 102 to the total thickness of the films of positive TCR material 104 may determine the amount of variation in sheet resistance Rₛ over a desired temperature range. Consequently, a particular ratio may be selected that minimizes that amount of variation, thus stabilizing the sheet resistance Rₛ and associated resistance of TFR structures 100A through 100D over the temperature range of interest.

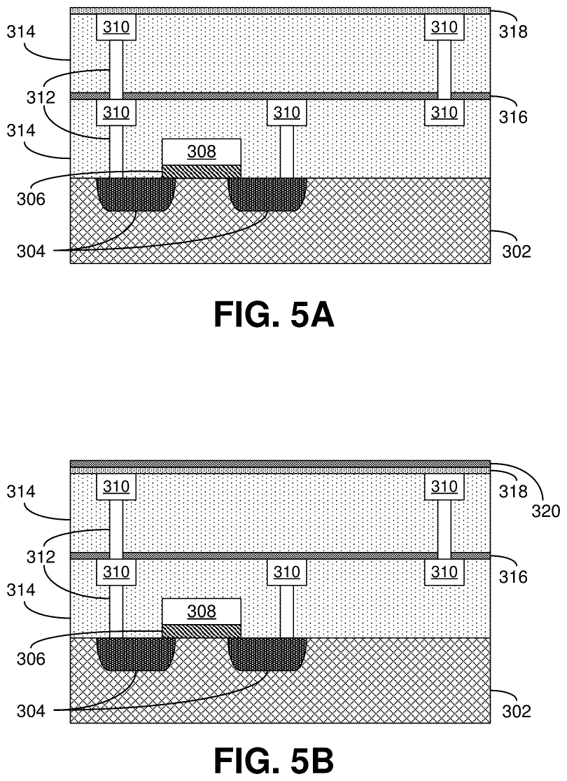

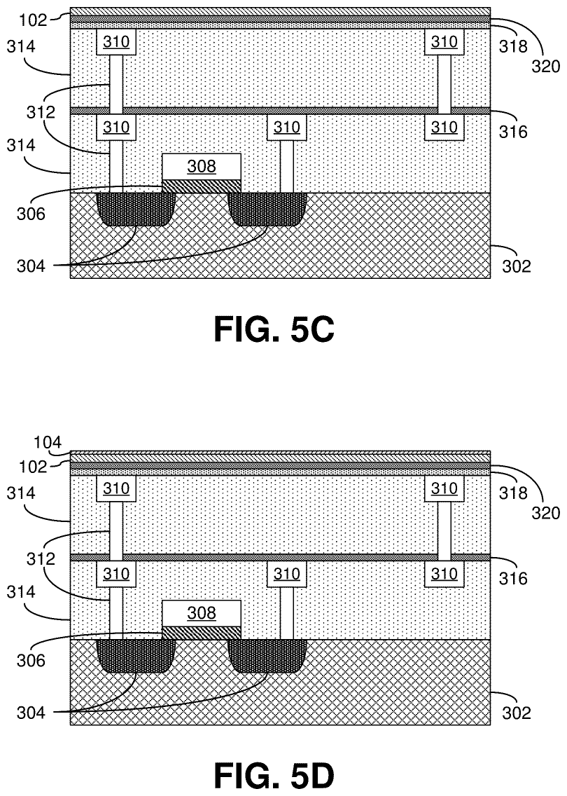

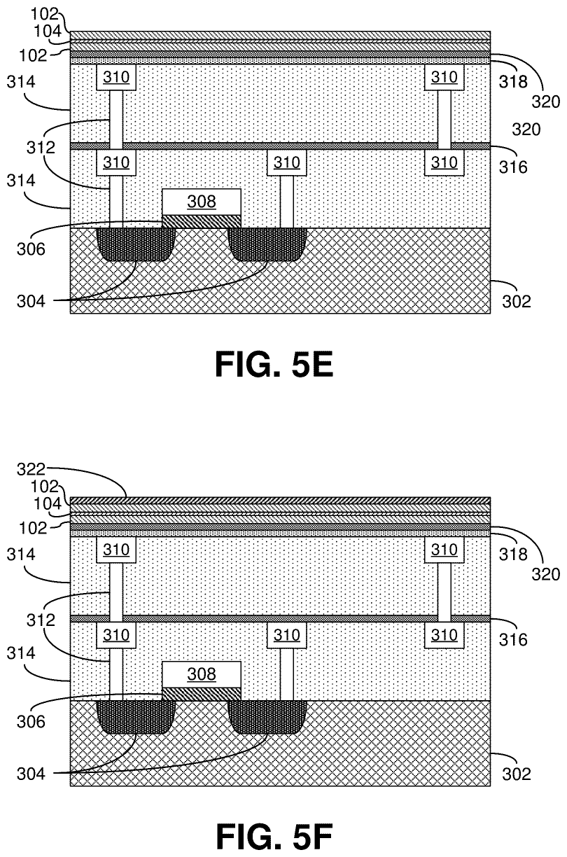

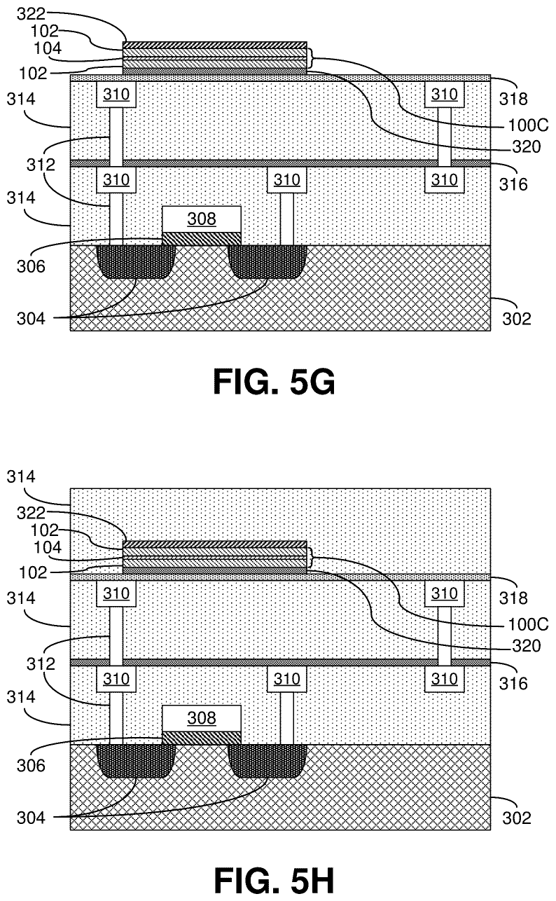

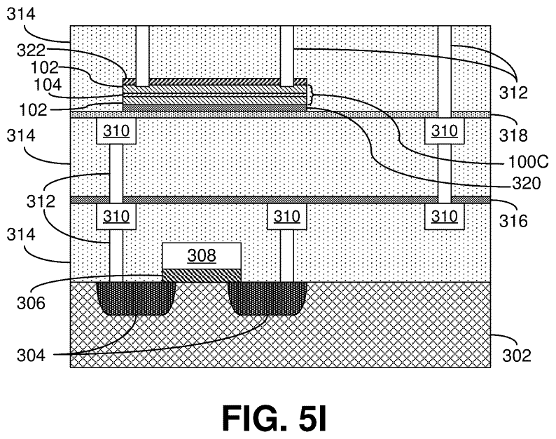

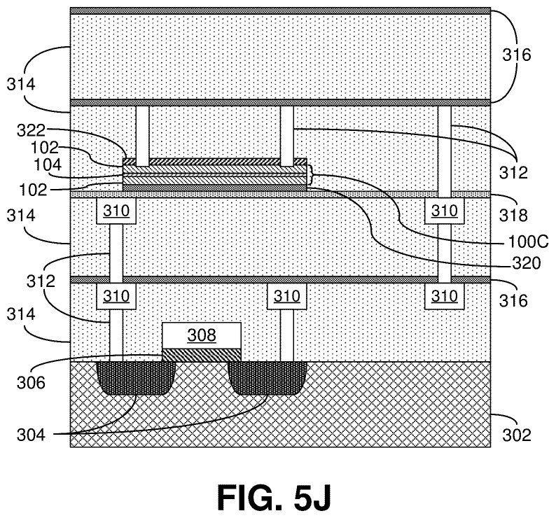

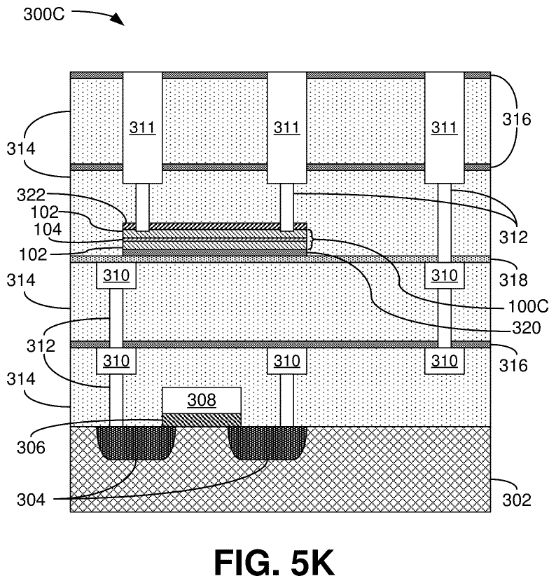

FIGS. 5A through 5K illustrate cross-sectional views of some embodiments of an IC device (e.g., IC device 300C of FIG. 4C) employing a TFR structure (e.g., TFR structure 100C of FIGS. 1C and 4C) at various stages of manufacture, according to the present disclosure. Although FIGS. 5A through 5K are described as a series of acts, it will be appreciated that these acts are not limiting in that the order of the acts within each series can be altered in other embodiments, and the methods disclosed are also applicable to other structures. In other embodiments, some acts that are illustrated and/or described may be omitted in whole or in part.

For example, FIG. 5A illustrates substrate 302, in which doped regions 304 are formed. Further, atop substrate 302 are dielectric layers 314, in which conductive structures 310 and interconnective vias 312, as well as gate structure 306 and associated conductive contact 308, are formed. In some embodiments, substrate 302 may be a p-type substrate and doped regions 304 may be n-doped regions. In some embodiments, consecutive dielectric layers 314 may be separated by an etch stop layer 316 or a barrier layer 318 to protect an upper surface of the underlying dielectric layer 314. The structure depicted in FIG. 5A, in some embodiments, may serve as an example starting substrate at which thin-film processing for creating a TFR structure (e.g., TFR structure 100C of FIGS. 1C and 4C) may begin.

FIG. 5B illustrates the forming (e.g., sputtering, evaporation, chemical vapor deposition (CVD), or other forms of thin-film deposition) of oxide layer 320 (e.g., silicon dioxide (SiO₂) or another dielectric material) that serves as a non-conductive base for TFR structure 100C to be formed thereon.

FIGS. 5C through 5E illustrate the forming (e.g., depositing, such as by sputtering, evaporation, CVD, or other forms of thin-film deposition) of first, second, and third films of TFR structure 100C (e.g., as shown in FIG. 4C). More specifically, first film of negative TCR material 102 is formed on oxide layer 320, as depicted in FIG. 5C. Thereafter, second film of positive TCR material 104 is formed on the first film, as shown in FIG. 5D. Then, in FIG. 5E, third film of negative TCR material 102 is formed on the second film. In other embodiments, other forms of TFR structure other than TFR structure 100C, such as TFR structures 100A, 100B, or 100D, may be formed on oxide layer 320 in other embodiments.

FIG. 5F illustrates the forming (e.g., depositing, such as by sputtering, evaporation, CVD, or other forms of thin-film deposition) of insulating film 322 (e.g., a nitride base film, such as silicon nitride (SiN), aluminum nitride (AlN), silicon carbide (SiC), or the like) on the third film.

FIG. 5G illustrates the removal (e.g., etching) of portions of oxide layer 320, first film of negative TCR material 102, second film of positive TCR material 104, third film of negative TCR material 102, and insulating film 322 to form TFR structure 100C, as well as non-conductive layers above and below TFR structure 100C. In some embodiments, other thin-film structures, such as other TFR structures, may be etched at the same time.

FIG. 5H illustrates the forming (e.g., deposition) of an additional dielectric layer 314 covering TFR structure 100 and surrounding portions of barrier layer 318.

FIG. 5I illustrates the forming (e.g., etching or trenching and subsequent deposition) of vias 312 in additional dielectric layer 314, including vias 312 serving as electrodes for TFR structure 100C. In some embodiments, the etching or trenching of vias 312 serving as electrodes may extend through insulating film 322 and to (or through) an upper surface of the third film of negative TCR material 102. In other embodiments, the electrodes may extend further into TFR structure 100C, including to and through an upper surface of oxide layer 320.

FIG. 5J illustrates the forming (e.g., deposition) of another etch stop layer 316, another dielectric layer 314, and a further etch stop layer 316, in order.

FIG. 5K illustrates the forming (e.g., trenching and subsequent deposition) of vias (e.g., TDVs 311) so that TDVs 311 extend from an upper surface of etch stop layer 316, through etch stop layer 316, further dielectric layer 314, additional etch stop layer 316, and dielectric layer 314 therebeneath to form vias 312, including vias 312 electrically contacting TFR structure 100C. Consequently, in some embodiments, TFR structure 100C may become a component of a larger circuit accessible by an upper surface of IC device 300C.

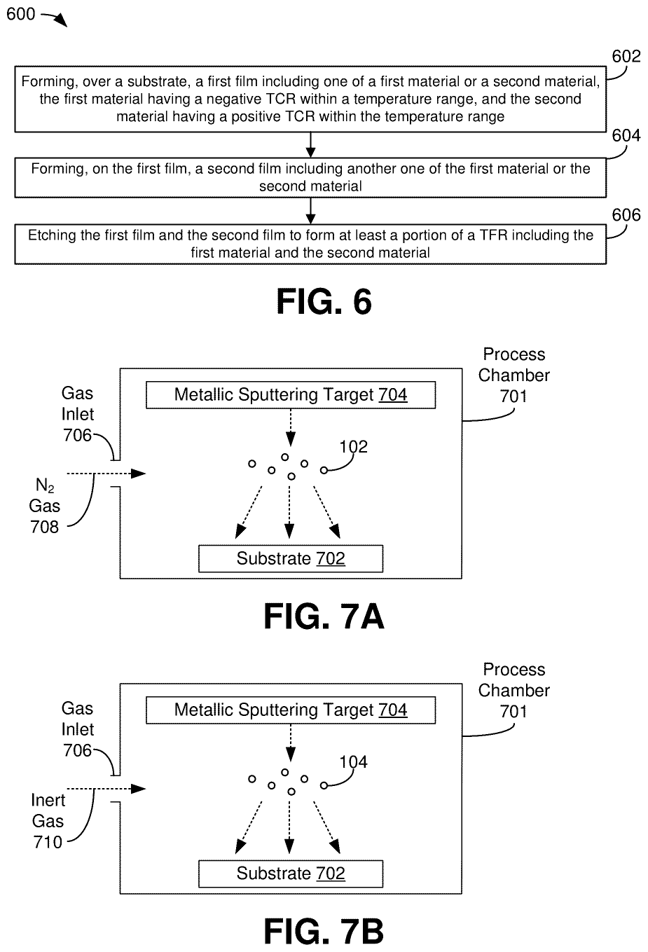

FIG. 6 illustrates a block diagram of some embodiments of a methodology 600 of forming an IC device (e.g., IC device 300C of FIG. 3C) including a TFR structure (e.g., TFR structure 100A, 100B, 100C, or 100D), according to the present disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At Act 602, a first film including one of a first material or a second material may be formed over a substrate (e.g. the structure depicted in FIG. 5A or FIG. 5B), where the first material has a negative TCR within a temperature range (e.g., negative TCR material 102 of FIGS. 1A through 1D) and the second material has a positive TCR within the temperature range (e.g., positive TCR material 104 of FIGS. 1A through 1D). FIG. 5C illustrates cross-sectional views of some embodiments corresponding to Act 602.

At Act 604, a second film including another one of the first material or the second material is formed on the first film. FIG. 5D illustrates a cross-sectional view of some embodiments corresponding to Act 604. In some embodiments, one or more additional films of alternating first and second materials may be stacked upon second film (e.g., FIG. 5E illustrates the forming of a third layer).

At Act 606, the first film and the second film are etched to form at least a portion of a TFR structure (e.g., TFR structure 100A, 100B, 100C, or 100D) including the first material and the second material. In some embodiments in which additional films are present, the etching of Act 606 may also etch the additional films simultaneously to form the TFR structure, as well as any non-conductive films (e.g., oxide layer 320 and insulating film 322 of FIG. 5G). FIG. 5G illustrates a cross-sectional view of some embodiments corresponding to Act 606.

FIGS. 7A and 7B illustrate schematic representations of forming (e.g., by sputtering) a first material having a negative TCR within a temperature range (e.g., negative TCR material 102) and a second material having a positive TCR within the temperature range (e.g., positive TCR material 104), respectively, of a thin-film resistor structure of an IC device, according to the present disclosure. In FIGS. 7A and 7B, a process chamber 701 may hold one or more substrates 702 (e.g., by way of a front-opening universal pod (FOUP) that may hold substrates 702 securely in a controlled environment for transfer between machines for processing and/or measurement). In some embodiments, each substrate 702 may include a partial IC device (e.g., as shown in FIG. 5B) upon which two or more films of alternating negative TCR material 102 and positive TCR material 104 may be formed (e.g., sputtered). Process chamber 701 may also include a gas inlet 706 (e.g., controlled by a valve) to allow a selected gas to flow into process chamber 701 to facilitate sputtering operations. Also provided in both FIGS. 7A and 7B is a metallic sputtering target 704 (e.g., including tantalum (Ta), titanium (Ti), or another metallic material) in process chamber 701.

In FIG. 7A, a reactive gas (e.g., nitrogen (N₂) gas 708) may be supplied by way of gas inlet 706 during a sputtering operation in which material (e.g., Ta, Ti, or another metal) ejected from metallic sputtering target 704 reacts with N₂ gas 708 to sputter negative TCR material 102 (e.g., tantalum nitride (TaN), titanium nitride (TiN), or another nitride base material) onto substrate 702. The sputtering operation may, for example, be performed during the method of FIGS. 5A-5K to deposit the negative TCR material 102 described with regard to FIGS. 5C and 5E. In some embodiments, higher flow rates of N₂ gas 708 may lead to higher concentrations of nitrogen in the negative TCR material 102, thus possibly causing a higher magnitude of the TCR (e.g., a more negative TCR value) for negative TCR material 102.

In FIG. 7B, an inert gas 710 (e.g., argon (Ar)) may flow into process chamber 701 to facilitate sputtering of positive TCR material 104 (e.g., Ta, Ti, or another metal) from metallic sputtering target 704 onto substrate 702. In some embodiments, such sputtering may occur in a vacuum instead of inert gas 710. The sputtering operation may, for example, be performed during the method of FIGS. 5A-5K to deposit the positive TCR material 104 described with regard to FIGS. 5C and 5E.

Consequently, alternating sputtering operations between those depicted in FIGS. 7A and 7B may cause the deposition of alternating films of negative TCR material 102 and positive TCR material 104 as described above by way of alternating the presence and/or type of gas being provided through gas inlet 706. Further, throughout the process, the same substrate 702 and metallic sputtering target 704 may be retained within process chamber 701, thus providing some level of protection to the substrate 702 from external environmental forces. Further, in some embodiments, various sputtering parameters (e.g., voltage, processing time, and the like) may be controlled to produce a desired thickness of each film (e.g., to provide a minimal TCR over a desired temperature range for the TFR structure 100 being produced, as discussed in detail above). Moreover, in some embodiments in which the last (uppermost) film of TFR structure 100 is negative TCR material 102, such a film may help prevent nitridation of the underlying positive TCR material 104 when substrate 702 is transferred from processing chamber 701 to another processing chamber (e.g., for subsequent deposition of insulating film 322, dielectric layer 314, or the like).

In some embodiments, the present disclosure provides an IC device, including: a thin-film resistor (TFR) overlying a substrate and comprising a first film and a second film that are stacked in a direction transverse to a top surface of the substrate, the first film including a first material having a negative temperature coefficient of resistance (TCR) within a temperature range, the negative TCR causes a resistance of the first film to decrease as a temperature of the first film increases, and the second film includes a second material having a positive TCR within the temperature range, the positive TCR causes a resistance of the second film to increase as a temperature of the second film increases. In some embodiments, the TFR has a combined TCR that is closer to zero than the negative TCR and the positive TCR. In some embodiments, the first material includes tantalum nitride (TaN), the second material includes tantalum (Ta), and a ratio of a thickness of the second film to a thickness of the first film is in a range from approximately 0.11 to approximately 0.22. In some embodiments, the ratio of the thickness of the second film to the thickness of the first film may be approximated by a ratio of the negative TCR of the first material to the positive TCR of the second material. In some embodiments, the ratio of the thickness of the second film to the thickness of the first film is in a range of between approximately 0.10 and approximately 0.20. In some embodiments, the IC device further includes a first electrode contacting the TFR at or proximate a first end of the TFR; and a second electrode contacting the TFR at or proximate a second end of the TFR opposite the first end of the TFR. In some embodiments, the first film overlies and directly contacts the second film, and the first electrode and the second electrode directly contact the first film. In some embodiments, the first film underlies and directly contacts the second film, and the first electrode and the second electrode directly contact the second film. In some embodiments, the TFR further includes a third film, the third film includes the first material, the third film is stacked with the first film and the second film in the direction, and the second film is between the first film and the third film in the direction. In some embodiments, the TFR further includes a third film, the third film includes the second material, the third film is stacked with the first film and the second film in the direction, and the first film is between the second film and the third film in the direction.

In some embodiments, the present disclosure provides another IC device, including: a thin-film resistor (TFR) arranged within an inter-level dielectric (ILD) layer and on a barrier layer over a substrate, the TFR including a plurality of films that are stacked in a direction extending away from the substrate, the plurality of films comprise a first material comprising a nitride of a metal and a second material comprising the metal, the second material is disposed entirely above or below the first material; a first conductive interconnect arranged on the TFR; and a second conductive interconnect arranged on the TFR and laterally separated from the first conductive interconnect, and the plurality of films have a combined TCR that is closer to zero than the first TCR and the second TCR. In some embodiments, the TFR has a sheet resistance that varies within a value range from approximately 12 ohms per square (Ω/□) to approximately 16 Ω/□ within the temperature range. In some embodiments, the first material includes tantalum nitride (TaN); and the second material includes tantalum (Ta). In some embodiments, the first material includes titanium nitride (TiN); and the second material includes titanium (Ti). In some embodiments, the first material has a first temperature coefficient of resistance (TCR) within a temperature range and the second material has a second TCR within the temperature range, the plurality of films have a combined TCR that has a smaller absolute value than the first TCR and the second TCR. In some embodiments, the IC device further includes: an insulator film positioned atop and sharing a width with the TFR, the insulating film being vertically arranged between the ILD layer and the TFR, the insulator film including at least one of silicon nitride (SiN), aluminum nitride (AlN), or silicon carbide (SiC).

In some embodiments, the present disclosure provides a method, including: forming, over a substrate, a first film including one of a first material or a second material; forming, on the first film, a second film including another one of the first material or the second material; and etching the first film and the second film to form at least a portion of a thin-film resistor (TFR) including the first material and the second material, the first material having a negative temperature coefficient of resistance (TCR) within a temperature range, and the second material having a positive TCR within the temperature range. In some embodiments, forming the first film includes sputtering the one of the first material or the second material in a process chamber, and forming the second film includes sputtering the other one of the first material or the second material in the process chamber. In some embodiments, sputtering the first material includes sputtering a metallic material toward the substrate in an atmosphere including a nitrogen (N₂) gas, and sputtering the second material includes sputtering the metallic material toward the substrate in an atmosphere comprising an inert gas. In some embodiments, a change in a flow rate of the N₂ gas modifies the negative TCR of the first material.

It will be appreciated that in this written description, as well as in the claims below, the terms “first”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a thin-film resistor (TFR) overlying a substrate, disposed in a dielectric layer, and comprising at least one first film and at least one second film, wherein:
a number of first films of the at least one first film equals, is one less than, or is one greater than a number of second films of the at least one second film;
the at least one first film and the at least one second film alternate along a vertical direction;
each of the at least one first film comprises a first material having a negative temperature coefficient of resistance (TCR) within a temperature range;
each of the at least one second film comprises a second material having a positive TCR within the temperature range;
a total thickness of the at least one first film is greater than a total thickness of the at least one second film when a magnitude of the negative TCR is less than a magnitude of the positive TCR; and
the total thickness of the at least one first film is less than the total thickness of the at least one second film when the magnitude of the negative TCR is greater than the magnitude of the positive TCR.

2. The IC device of claim 1, wherein the number of first films is two, and the number of second films is one.

3. The IC device of claim 1, wherein the number of first films is one, and the number of second films is two.

4. The IC device of claim 1, wherein the number of first films is one, and the number of second films is one.

5. The IC device of claim 4, wherein the one first film is on the one second film.

6. The IC device of claim 4, wherein the one second film is on the one first film.

7. The IC device of claim 1, wherein:
the first material comprises a nitride of a metallic material; and
the second material comprises the metallic material.

8. The IC device of claim 1, wherein:
the first material comprises tantalum nitride (TaN); and
the second material comprises tantalum (Ta).

9. The IC device of claim 1, wherein:
the first material comprises titanium nitride (TiN); and
the second material comprises titanium (Ti).

10. The IC device of claim 1, wherein a ratio of the total thickness of the at least one second film to the total thickness of the at least one first film is approximately equal to a ratio of the negative TCR to the positive TCR.

11. The IC device of claim 1, further comprising:
a first electrode extending downward to contact an upper side of the TFR at or proximate to a first lateral end of the TFR; and
a second electrode extending downward to contact the upper side of the TFR at or proximate to a second lateral end of the TFR opposite the first lateral end of the TFR.

12. The IC device of claim 1, further comprising an insulator film on, and sharing a width and length with, the TFR in a plan view of the IC device.

13. The IC device of claim 1, further comprising a barrier layer underlying, and sharing a width and length with, the TFR in a plan view of the IC device.

14. A method comprising:
depositing, over a substrate, alternating films of a first material and a second material; and
etching the alternating films to form at least a portion of a thin-film resistor (TFR), wherein
the first material has a negative temperature coefficient of resistance (TCR) within a temperature range;
the second material has a positive TCR within the temperature range;
a total thickness of the first material is greater than a total thickness of the second material when a magnitude of the negative TCR is less than a magnitude of the positive TCR; and
the total thickness of the first material is less than the total thickness of the second material when the magnitude of the negative TCR is greater than the magnitude of the positive TCR.

15. The method of claim 14, wherein depositing the alternating films comprises:
sputtering, for the first material, a metallic material toward the substrate in an atmosphere comprising a nitrogen (N₂) gas; and
sputtering, for the second material, the metallic material toward the substrate in an atmosphere comprising an inert gas.

16. The method of claim 15, the metallic material comprising at least one of tantalum (Ta) or titanium (Ti).

17. The method of claim 15, the inert gas comprising argon (Ar).

18. The method of claim 14, wherein depositing the alternating films comprises:
sputtering, for the first material, a metallic material toward the substrate in an atmosphere comprising a nitrogen (N₂) gas; and
sputtering, for the second material, the metallic material toward the substrate in a vacuum.

19. A method comprising:
depositing, over a substrate, a barrier layer;
depositing, on the barrier layer, alternating films of a first material and a second material, wherein
the first material has a negative temperature coefficient of resistance (TCR) within a temperature range; and
the second material has a positive TCR within the temperature range;
depositing, on an uppermost film of the alternating films, an insulator film;
etching the insulator film, the alternating films, and the barrier layer to form at least a portion of a thin-film resistor (TFR);
depositing a dielectric layer on and surrounding the TFR;
etching, through the dielectric layer and the insulator film, a first opening and a second opening at opposing ends of the TFR; and
depositing a conductive material in the first opening and the second opening to form a first electrode and a second electrode, respectively, for the TFR.

20. The method of claim 19, wherein:
the first material comprises a nitride of a metallic material; and
the second material comprises the metallic material.
